(19) United States
(12) Patent Application Publication
(10) Pub. No.: US 2026/0009135 A1
(43) Pub. Date: Jan. 8, 2026

(54) APPARATUS FOR MANUFACTURING DISPLAY DEVICE AND METHOD OF MANUFACTURING DISPLAY DEVICE

(71) Applicant: Samsung Display Co., Ltd., Yongin-Si (KR)

(72) Inventor: Sungmin Huch, Yongin-si (KR)

(21) Appl. No.: 19/029,464

(22) Filed: Jan. 17, 2025

(30) Foreign Application Priority Data
Jul. 5, 2024 (KR) 10-2024-0089113

(51) Int. Cl. C23C 16/458

(52) U.S. Cl. CPC C23C 16/4581; C23C 16/4583

(57) ABSTRACT

An apparatus for manufacturing a display device includes a chamber, a susceptor positioned inside the chamber and configured to support a display substrate, and a spray portion positioned to spray a deposition material toward the susceptor, wherein a surface roughness of the susceptor is about 19 μm to about 23 μm.

### CROSS-REFERENCE TO RELATED APPLICATION

This application is based on and claims priority, under 35 U.S.C. § 119, to Korean Patent Application No. 10-2024-0089113 filed on Jul. 5, 2024 in the Korean Intellectual Property Office, the disclosure of which is incorporated by reference herein in its entirety.

### BACKGROUND

### 1. Field

The disclosure relates to an apparatus for manufacturing a display device and a manufacturing method for a display device, and more particularly, to an apparatus for manufacturing a display device and a manufacturing method for a display device capable of reducing defects occurring during a manufacturing process.

### 2. Description of the Related Art

A display device includes a plurality of thin films, and the plurality of thin films may be formed using a vapor deposition method. In a vapor deposition method, one or more gases are used as raw materials to form a thin film, and there are various vapor deposition methods such as chemical vapor deposition (CVD) and atomic layer deposition (ALD).

As display devices become larger and higher resolution is required, it becomes challenging to deposit large-area thin films with desired properties. There are also limits to improving the efficiency of the process of forming these thin films.

### SUMMARY

However, in display devices according to the related art, defects may be generated if the display devices include a silicon-based insulating layer formed by an apparatus for manufacturing a display device that has been used for a long period of time.

One or more embodiments include an apparatus for manufacturing a display device and a manufacturing method of a display device, whereby the possibility of defects occurring during a manufacturing process may be reduced.

Additional aspects will be set forth in part in the description which follows and, in part, will be apparent from the description, or may be learned by practice of the presented embodiments of the disclosure.

According to one or more embodiments, an apparatus for manufacturing a display device includes a chamber, a susceptor positioned inside the chamber and configured to support a display substrate, and a spray portion positioned to spray a deposition material toward the susceptor, wherein a surface roughness of the susceptor is about 19 μm to about 23 μm.

The susceptor may have a flatness of about 200 μm to about 500 μm.

The susceptor may include a first metal layer and a first metal oxide layer disposed on the first metal layer.

The first metal layer may include at least one of aluminum, magnesium, zinc, manganese, and copper.

The first metal oxide layer may include a same metal element as that of the first metal layer.

An oxygen content of the first metal oxide layer may be higher than an oxygen content of the first metal layer.

The first metal oxide layer may include an oxide of at least one of aluminum, magnesium, zinc, manganese, and copper.

The first metal layer may include aluminum, and the first metal oxide layer may include aluminum oxide.

A thickness of the first metal oxide layer may be about 7 μm to about 10 μm.

The first metal layer and the first metal oxide layer may form a single body.

According to one or more embodiments, a method of manufacturing a display device includes mounting a display substrate on a susceptor inside a chamber, the susceptor having a surface roughness of about 19 μm to about 23 μm, and spraying a deposition material onto the display substrate by using a spray portion directed toward the display substrate.

A flatness of the susceptor may be about 200 μm to about 500 μm.

The susceptor may include a first metal layer and a first metal oxide layer disposed on the first metal layer.

The first metal layer may include at least one of aluminum, magnesium, zinc, manganese, and copper.

The first metal oxide layer may include a same metal element as that of the first metal layer.

An oxygen content of the first metal oxide layer may be higher than an oxygen content of the first metal layer.

The first metal oxide layer may include an oxide of at least one of aluminum, magnesium, zinc, manganese, and copper.

The first metal layer may include aluminum, and the first metal oxide layer may include aluminum oxide.

A thickness of the first metal oxide layer may be about 7 μm to about 10 μm.

The first metal layer and the first metal oxide layer may form a single body.

Other aspects, features and advantages other than those described above will become apparent from the following detailed description, claims and drawings for practicing the disclosure.

### BRIEF DESCRIPTION OF THE DRAWINGS

the and other aspects, features, and advantages of certain embodiments of the disclosure will be more apparent from the following description taken in conjunction with the accompanying drawings, in which:

FIG. 1 is a cross-sectional view schematically illustrating an apparatus for manufacturing a display device, according to an embodiment;

FIG. 2 is a schematic, enlarged cross-sectional view of portion A of FIG. 1;

FIG. 3 is a microscopic photographic image of a susceptor included in an apparatus for manufacturing a display device, according to an embodiment;

FIG. 4 is a graph showing a number of display devices with defects according to a number of display substrates on which a silicon-based insulating layer is formed using an apparatus for manufacturing a display device;

FIG. 5 is a graph showing a number of display devices with defects according to a number of display substrates on which a silicon-based insulating layer is formed using an apparatus for manufacturing a display device;

FIG. 6 is a microscopic photographic image of a susceptor included in an apparatus for manufacturing a display device, according to an embodiment;

FIG. 7 is a flowchart of a method of manufacturing a display device, according to an embodiment; and

FIG. 8 is a cross-sectional view schematically illustrating a display device manufactured according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The effects and features of the disclosure, and ways to achieve them will become apparent by referring to embodiments that will be described later in detail with reference to the drawings. However, the disclosure is not limited to the following embodiments but may be embodied in various forms.

In the present specification, it will be understood that ordinal terms “first”, “second”, etc. may be used herein to distinguish one element from another. Hence, elements should not necessarily be limited to a certain order or priority based on the ordinal terms.

In the present specification, singular expressions, unless defined otherwise in contexts, include plural expressions.

In the present specification, it will be further understood that the terms “comprise” and/or “have” used herein specify the presence of stated features or elements, but do not preclude the presence or addition of one or more other features or elements.

Herein, “A and/or B” may indicate A, B, or both A and B. Also, “at least one of A and B” may indicate only A, only B, or both A and B.

In the present specification, it will be understood various elements such as a layer, a film, an area, or a plate being “on” or “above” another element refers to being directly on or above the other element, or an intervening element may also be present.

In the present specification, layers, regions, or elements being “connected” indicates a case where layers, regions, and elements are directly connected or/and a case where layers, regions, and elements are indirectly connected with other layers, regions, and elements therebetween. For example, herein, layers, regions, or elements being electrically connected indicates a case where layers, regions, and elements are directly electrically connected and/or a case where layers, regions, and elements are indirectly electrically connected with other layers, regions, and elements therebetween.

In the present specification, an x-axis, a y-axis, and a z-axis are not limited to three axes on a rectangular coordinates system but may be construed as including these axes. For example, an-x axis, a y-axis, and a z-axis may be at right angles or may also indicate different directions from one another, which are not at right angles.

When an embodiment is implementable in another manner, a certain process order may be different from a described one. For example, two processes that are consecutively described may be substantially simultaneously performed or may be performed in an opposite order to the described order.

Hereinafter, embodiments of the disclosure will be described in detail with reference to the accompanying drawings, and in the description with reference to the drawings, like reference numerals refer to like elements and redundant descriptions thereof will be omitted. In the drawings, for convenience of description, sizes of elements may be exaggerated or contracted. For example, since sizes and thicknesses of elements in the drawings are arbitrarily illustrated for convenience of explanation, the following embodiments are not limited thereto.

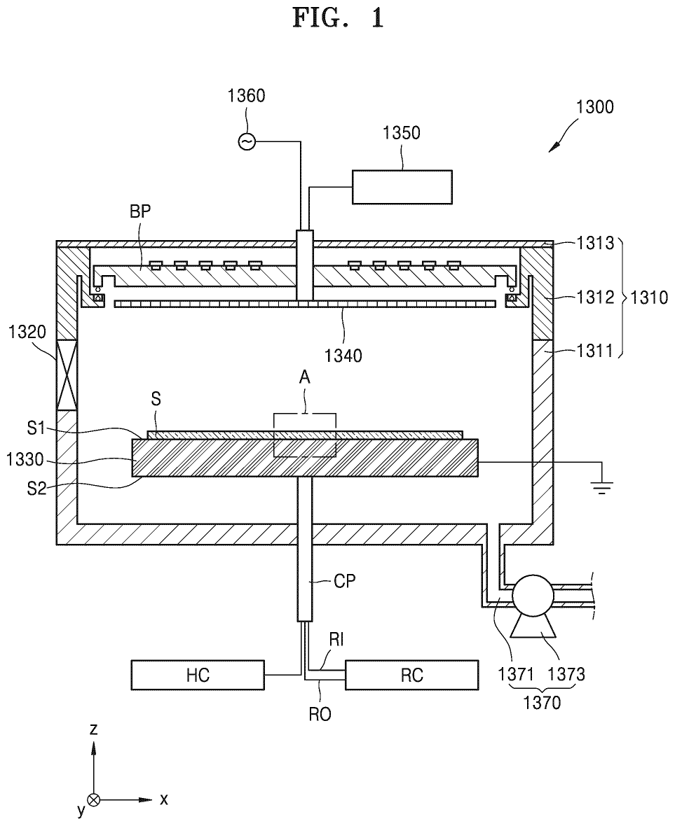

FIG. 1 is a cross-sectional view schematically illustrating an apparatus 1300 for manufacturing a display device, according to an embodiment. In FIG. 1, a display substrate S is also illustrated for convenience of description.

Referring to FIG. 1, the apparatus 1300 for manufacturing a display device may include a chamber 1310 that defines a space, an opening/closing portion 1320 that can connect the space inside the chamber 1310 with area outside the chamber 1310, a susceptor 1330, a spray portion 1340, a deposition material supply portion 1350, a power supply portion 1360, a pressure control portion 1370, a driving portion CP, a heater control portion HC, and a refrigerant control portion RC.

By using the apparatus 1300 for manufacturing a display device, components included in a display device may be manufactured. For example, using the apparatus 1300 for manufacturing a display device, a silicon-based insulating layer included in a display device may be formed. The apparatus 1300 for manufacturing a display device may include a chemical vapor deposition (CVD) device or a plasma enhanced chemical vapor deposition (PECVD) device.

The display substrate S may be moved into the space inside the chamber 1310 or taken out via the opening/closing portion 1320. In other words, the chamber 1310 may have a space therein, and the display substrate S may be withdrawn from this space or placed in this space. In an embodiment, the opening/closing portion 1320 including a gate valve may be arranged in an open portion of the chamber 1310 and be selectively opened/closed. With the opening/closing portion 1320 opened, the display substrate S may be loaded into the chamber 1310.

The chamber 1310 may include a first portion 1311, a second portion 1312, and a third portion 1313. The first portion 1311 may correspond to a chamber body. The second portion 1312 may be disposed on the first portion 1311. The second portion 1312 may correspond to a lid. The third portion 1313 may correspond to a cover plate. The third portion 1313 may be arranged to cover a backing plate BP. The backing plate BP may protect the inside of the chamber 1310 from the atmospheric environment and prevent a deposition material sprayed from the spray portion 1340 from leaking out. In an embodiment, a plurality of refrigerant flow paths may be arranged on the backing plate BP.

The display substrate S may be mounted on the susceptor 1330 arranged inside the chamber 1310. In other words, the susceptor 1330 may be inside the chamber 1310, and the display substrate S may rest on the susceptor 1330. The susceptor 1330 may include a first surface S1 facing the spray portion 1340 and a second surface S2 facing away from the spray portion 1340. The display substrate S may be disposed on the first surface S1 of the susceptor 1330. That is, the susceptor 1330 may support the display substrate S.

In an embodiment, the susceptor 1330 may not be flat. For example, a center of the susceptor 1330 may protrude in a +z direction more than an edge of the susceptor 1330, forming a curved shape. The display substrate S may be placed on the center of the susceptor 1330. However, the disclosure is not limited thereto. The center of the susceptor 1330 may be formed integrally with the edge of the susceptor 1330.

The susceptor 1330 may include at least one of aluminum (Al), magnesium (Mg), zinc (Zn), manganese (Mn), and copper (Cu). For example, the susceptor 1330 may include aluminum (Al). Alternatively, the susceptor 1330 may include an aluminum (Al)-zinc (Zn)-magnesium (Mg) alloy.

The driving portion CP may be connected to and disposed below the susceptor 1330. The driving portion CP may adjust a position of the susceptor 1330. Therefore, the susceptor 1330 may be lifted or lowered. For example, the driving portion CP may include a cylinder. Alternatively, the driving portion CP may include a linear motor. Alternatively, the driving portion CP may include a rack and pinion. However, the disclosure is not limited thereto, and the driving portion CP may include any devices and structures that control the position of the susceptor 1330.

The susceptor 1330 may control temperature of the display substrate S. For example, the susceptor 1330 may include a flow path through which a refrigerant circulates and/or a heater. That is, the temperature of the display substrate S mounted on the susceptor 1330 may be controlled by circulating a refrigerant such as cooling water through the flow path of the susceptor 1330 or by generating heat through the heater of the susceptor 1330. As the susceptor 1330 includes the flow path through which a refrigerant circulates and/or the heater, the susceptor 1330 may satisfy various process conditions.

A heater wire connected to the heater of the susceptor 1330 may pass through the inside of the driving portion CP and be connected to the heater control portion HC. Additionally, a refrigerant inlet RI and a refrigerant outlet RO, which are connected to the flow path of the susceptor 1330, through which a refrigerant circulates, may pass through the driving portion CP and be connected to the refrigerant control portion RC.

The heater control portion HC may be connected to the heater of the susceptor 1330 and control the temperature of the heater. The refrigerant control portion RC may be connected to the flow path of the susceptor 1330 and control the temperature of the refrigerant. The refrigerant control portion RC may be configured to supply, through the refrigerant inlet RI, a refrigerant to the susceptor 1330, through which the refrigerant circulates. Additionally, the refrigerant control portion RC may receive the refrigerant that circulated through the susceptor 1330 via the refrigerant outlet RO. The refrigerant may include perfluoropolyether (PFPE). For example, the refrigerant may include a Galden solution.

The spray portion 1340 may supply a deposition material into the chamber 1310. The spray portion 1340 may include a plurality of nozzles, and the deposition material may be sprayed into the chamber 1310 through the plurality of nozzles. The deposition material may include a gas including a component that is a raw material for a layer to be formed on the display substrate S. For example, the deposition material may include a gas including components that are raw materials for a silicon-based insulating layer, such as silicon (Si), oxygen (O), or nitrogen (N).

In an embodiment, the spray portion 1340 and the susceptor 1330 may function as two electrodes for forming a plasma. For example, the spray portion 1340 may be connected to the power supply portion 1360. The susceptor 1330 may be grounded. Accordingly, when the spray portion 1340 sprays the deposition material, plasma may be formed between the spray portion 1340 and the susceptor 1330. As the deposition material passes through a region where plasma is formed, radicals are formed, and the radicals may react on the display substrate S to form a silicon-based insulating layer. In this manner, a deposition process of a silicon-based insulating layer may be performed using plasma.

The deposition material supply portion 1350 may supply the deposition material to the spray portion 1340. Additionally, the deposition material supply portion 1350 may store the deposition material.

The power supply portion 1360 may be electrically connected to the spray portion 1340. In an embodiment, the power supply portion 1360 may supply alternating current (AC) power to the spray portion 1340. In this case, the spray portion 1340 may function as an upper electrode, and the susceptor 1330 may function as a lower electrode. Thus, plasma may be formed between the spray portion 1340 and the susceptor 1330.

The pressure control portion 1370 may include a connecting pipe 1371 connected to the chamber 1310 and a pump 1373 installed on the connecting pipe 1371. According to operation of the pump 1373, outside air may be introduced through the connecting pipe 1371, or gas inside the chamber 1310 may be guided to the outside through the connecting pipe 1371.

Although not shown, the apparatus 1300 for manufacturing a display device may further include a mask frame. The mask frame may be arranged between the susceptor 1330 and the spray portion 1340. In an embodiment, the mask frame may be fixed inside the chamber 1310. The mask frame may shield edges of the display substrate S. Accordingly, the mask frame may prevent the deposition material sprayed from the spray portion 1340 from being deposited on the edges of the display substrate S.

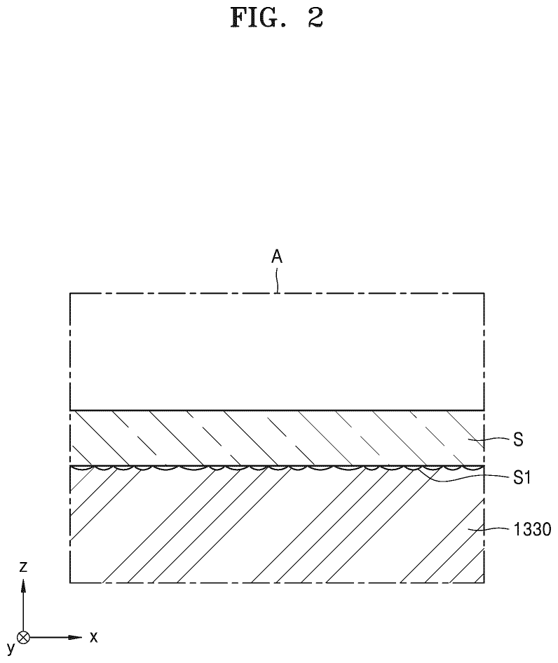

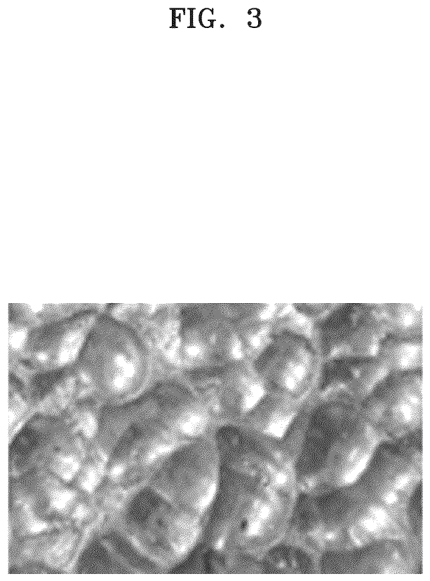

FIG. 2 is a schematic, enlarged cross-sectional view of portion A of FIG. 1, and FIG. 3 is a microscopic photographic image of the susceptor 1330 included in the apparatus 1300 for manufacturing a display device, according to an embodiment. FIG. 3 is an optical microscopic photographic image of the first surface S1 of the susceptor 1330 included in the apparatus 1300 for manufacturing a display device, according to an embodiment.

Referring to FIGS. 2 and 3, the susceptor 1330 may have surface roughness. As described above, the susceptor 1330 may include the first surface S1 facing the spray portion 1340, and the first surface S1 may not be flat. That is, the first surface S1 of the susceptor 1330 may have roughness. In this specification, the roughness of the first surface S1 of the susceptor 1330 may be referred to as a surface roughness of the susceptor 1330 or the roughness of a surface of the susceptor 1330, and the surface roughness or roughness refers to an arithmetic mean roughness Ra. A method of measuring the arithmetic mean roughness Ra of a surface of a certain member is obvious to those skilled in the art, and thus detailed description thereof is omitted.

The susceptor 1330 is manufactured by processing a base material into a shape of the susceptor 1330 to manufacture a preliminary susceptor, performing a bead blasting process on one side of the preliminary susceptor, and then performing an anodizing process on the surface of the preliminary susceptor where the bead blasting process has been performed. The bead blasting process is a process of spraying beads, such as SiO₂ and/or Al₂O₃ particles, at high pressure, to form fine irregularities on one surface of the preliminary susceptor. That is, by performing a bead blasting process on one surface of the preliminary susceptor, a roughness or texture is created on the surface of the susceptor 1330. The anodizing process is a process of oxidizing a surface of a metal material, and the surface of the susceptor 1330 finally produced may include metal oxide formed by the anodizing process.

In an embodiment, the first surface S1 of the susceptor 1330 may have a plurality of concave shaped—i.e., a spherical negative shaped—grooves. For example, in the manufacturing process of the susceptor 1330, a bead blasting process may be performed by spraying spherical SiO₂ particles having a diameter of about 0.5 mm to about 2.0 mm or less onto a surface of the preliminary susceptor at high pressure. With this process, the susceptor 1330 may have concave shaped grooves that are about the size of the spherical SiO₂ particles.

In an embodiment, the surface roughness of the susceptor 1330 may be about 19 μm to about 23 μm. Alternatively, the surface roughness of the susceptor 1330 may be about 20 μm to about 22 μm. Alternatively, the surface roughness of the susceptor 1330 may be about 20.5 μm to about 21.5 μm. If the surface roughness of the susceptor 1330 is below the above range, a defect may occur in a display device including a silicon-based insulating layer formed by the apparatus 1300 after the apparatus 1300 has been used for a long period of time. If the surface roughness of the susceptor 1330 exceeds the above range, the degree to which an electric field concentrates in a certain portion of the susceptor 1330 may increase, which may cause arcing.

In general, charges may accumulate on the display substrate S due to static electricity generated in a process prior to the process of forming a silicon-based insulating layer. Charges may also accumulate on the susceptor 1330 of the apparatus 1300 for manufacturing a display device, due to static electricity. The degree of charge accumulation on the display substrate S may vary depending on a location of the display substrate S, and the degree of charge accumulation on the susceptor 1330 may vary depending on the location of the susceptor 1330. Depending on a difference in the degree of charge accumulation at each location of the display substrate S and a difference in the degree of charge accumulation at each location of the susceptor 1330, a gap between the display substrate S and the susceptor 1330 may differ. For example, the gap between a portion of the display substrate S, where a large amount of charges has accumulated, and a portion of the susceptor 1330 may be larger than a gap between a portion of the display substrate S, where a large amount of charges has not accumulated, and the portion of the susceptor 1330.

As described above, the apparatus 1300 performs a deposition process using plasma, and a large amount of charges is generated during the deposition process. A large amount of charges generated during the deposition process may accumulate on the display substrate S. Accordingly, a gap between the portion of the display substrate S on which a large amount of charges accumulates and a portion of the susceptor 1330 may become larger. As a consequence, the display substrate S may become warped. If the susceptor 1330 is used for a long period of time, the susceptor 1330 is physically and/or chemically worn out, and some of metal oxide on the surface of the susceptor 1330 is removed. Accordingly, an electric field is concentrated on the portion of the susceptor 1330 from which the metal oxide on the surface is removed, and charges may accumulate. Accordingly, as the surface of the susceptor 1330 is electrically uneven, warping may occur more easily on the display substrate S.

When a deposition material is deposited on the display substrate S where such warping occurs to form a silicon-based insulating layer, the silicon-based insulating layer may be formed unevenly. A display device including the silicon-based insulating layer as above may have defects (e.g., color abnormalities). That is, defects may occur during the manufacturing process of a display device.

Meanwhile, the amount of static electricity between a metal plate and a semiconductor plate arranged between two metal plates is inversely proportional to the distance between the surface of the metal plate and the surface of the semiconductor plate. In the present embodiment, the susceptor 1330 has a relatively large surface roughness. As the surface roughness of the susceptor 1330 is relatively high, the distance between a surface of the susceptor 1330 and a surface of the display substrate S may be relatively large. Therefore, the amount of static electricity between the susceptor 1330 and the display substrate S may be relatively small. Accordingly, a difference in the degree of charge accumulation according to a position of the display substrate S or a difference in the degree of charge accumulation according to the position of the susceptor 1330 may be small. Accordingly, warping on the display substrate S may be reduced or prevented.

Accordingly, even when the apparatus 1300 for manufacturing a display device performs a deposition process using plasma, the silicon-based insulating layer formed by depositing a deposition material on the display substrate S may not be formed unevenly. That is, the possibility of defects occurring during the manufacturing process of a display device may be reduced.

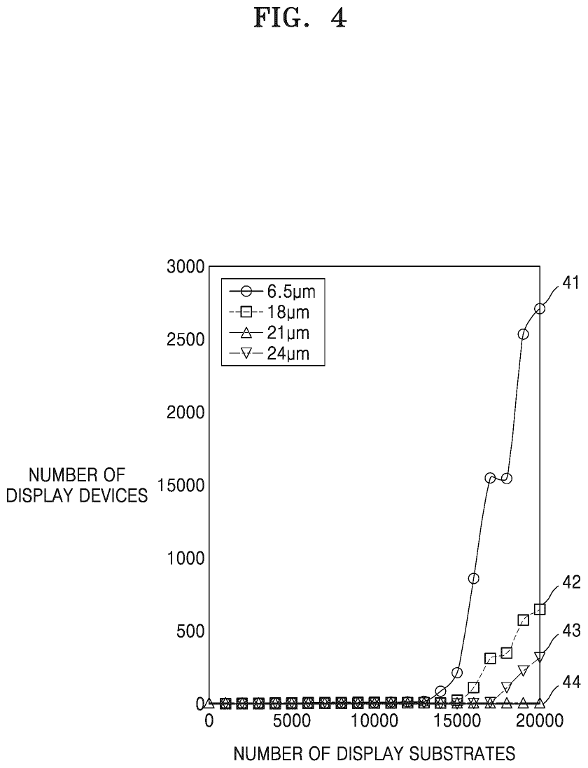

FIG. 4 is a graph showing the number of display devices with defects according to the number of display substrates S on which a silicon-based insulating layer is formed using the apparatus 1300 for manufacturing a display device. In FIG. 4, the horizontal axis represents the number of display substrates S on which a silicon-based insulating layer is formed using the apparatus 1300 for manufacturing a display device, and the vertical axis represents the number of display devices in which a defect has occurred. A display device of a graph 41 includes a silicon-based insulating layer formed using the susceptor 1330 having a roughness of 6.5 μm, and a display device of a graph 42 includes a silicon-based insulating layer formed using the susceptor 1330 having a roughness of 18 μm. A display device of a graph 43 includes a silicon-based insulating layer formed using the susceptor 1330 having a roughness of 21 μm, and a display device of a graph 44 includes a silicon-based insulating layer formed using the susceptor 1330 having a roughness of 24 μm.

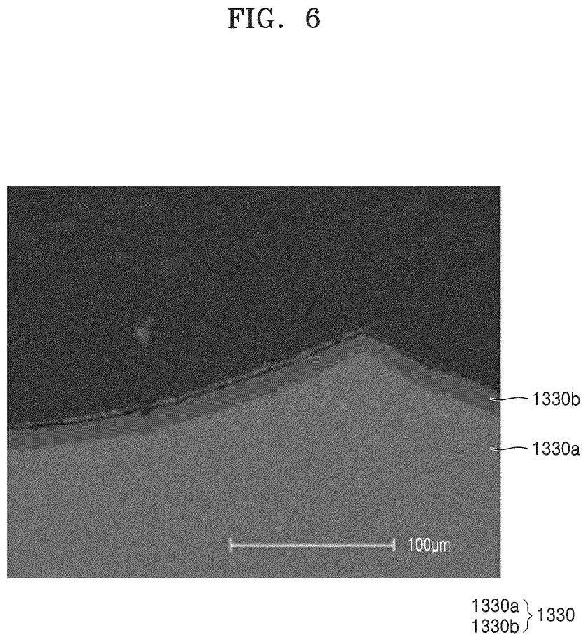

The susceptors 1330 used for forming a silicon-based insulating layer included in each of the display device of the graph 41, the display device of the graph 42, the display device of the graph 43 and the display device of the graph 44 have the same or similar flatness. In addition, the susceptors 1330 used for forming the silicon-based insulating layer included in each of the display device of the graph 41, the display device of the graph 42, the display device of the graph 43, and the display device of the graph 44 have a first metal oxide layer (1330b, see FIG. 6) of the same or similar thickness.

Referring to FIG. 4, with a silicon-based insulating layer that was formed using the susceptor 1330 having a roughness of 6.5 μm, a defect occurred in the display device for the first time after the apparatus 1300 for manufacturing a display device was used approximately 13,000 times. In addition, with a silicon-based insulating layer that was formed using the susceptor 1330 having a roughness of 6.5 μm, defects occurred in approximately 2,714 display devices out of 20,000 display devices.

With a silicon-based insulating layer that was formed using the susceptor 1330 having a roughness of 18 μm, a defect occurred in the display device for the first time after the apparatus 1300 for manufacturing a display device was used approximately 15,000 times. With a silicon-based insulating layer that was formed using the susceptor 1330 having a roughness of 18 μm, defects occurred in approximately 645 display devices out of 20,000 display devices. With a silicon-based insulating layer was formed using the susceptor 1330 having a roughness of 21 μm, a defect occurred in the display device for the first time after the apparatus 1300 for manufacturing a display device was used approximately 17,000 times. With a silicon-based insulating layer was formed using the susceptor 1330 having a roughness of 21 μm, defects occurred in approximately 314 display devices out of 20,000 display devices. That is, if the surface roughness of the susceptor 1330 satisfies the above-described range, defects may be prevented or reduced in a display device including a silicon-based insulating layer formed by using the apparatus 1300 for manufacturing a display device, which has been used for a long period of time.

With a silicon-based insulating layer was formed using the susceptor 1330 having a roughness of 24 μm, no defects occurred in the display device even after the apparatus 1300 for manufacturing a display device was used approximately 20,000 times. However, if forming a silicon-based insulating layer using the susceptor 1330 having a roughness of 24 μm, arcing occurred while forming the silicon-based insulating layer.

In an embodiment, the flatness of the susceptor 1330 may be about 200 μm to about 500 μm. Alternatively, the flatness of the susceptor 1330 may be about 300 μm to about 400 μm. Alternatively, the flatness of the susceptor 1330 may be about 330 μm to about 370 μm. The flatness may be a difference between highest and lowest heights of the first surface S1 of the susceptor 1330 with respect to an imaginary reference plane parallel to a lower surface of the chamber 1310. A person skilled in the art would know how to measure the flatness of a surface, and thus detailed description thereof is omitted. If the flatness of the susceptor 1330 is below the above range or if the flatness of the susceptor 1330 exceeds the above range, a defect may occur in a display device including a silicon-based insulating layer formed by the apparatus 1300 for manufacturing a display device after some time.

As described above, the amount of static electricity between a metal plate and a semiconductor plate arranged between two metal plates is inversely proportional to the distance between a surface of the metal plate and a surface of the semiconductor plate. In the present embodiment, the susceptor 1330 has a high flatness. As the flatness of the susceptor 1330 is high, a distance difference between a surface of the susceptor 1330 and a surface of the display substrate S may also be high. Therefore, there may not be much static electricity between the susceptor 1330 and the display substrate S. Accordingly, a difference in the degree of charge accumulation according to a position of the display substrate S or a difference in the degree of charge accumulation according to a position of the susceptor 1330 may be small. Accordingly, warping on the display substrate S may be prevented or reduced.

Accordingly, even if the apparatus 1300 for manufacturing a display device performs a deposition process using plasma, the silicon-based insulating layer formed by depositing the deposition material on the display substrate S may not be formed unevenly. That is, the possibility of defects occurring during the manufacturing process of a display device may be reduced.

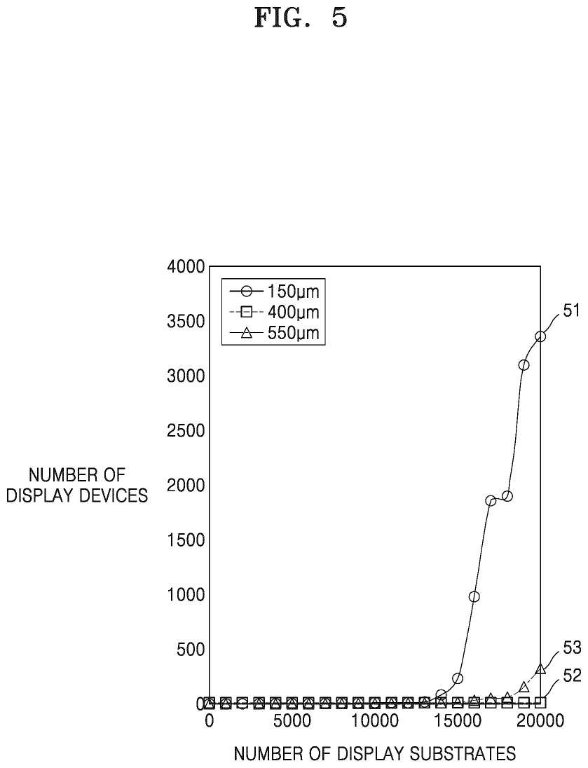

FIG. 5 is a graph showing the number of display devices with defects according to the number of display substrates S on which a silicon-based insulating layer is formed using the apparatus 1300 for manufacturing a display device. In FIG. 5, the horizontal axis represents the number of display substrates S on which a silicon-based insulating layer is formed using the apparatus 1300 for manufacturing a display device, and the vertical axis represents the number of display devices in which a defect has occurred. A display device of a graph 51 includes a silicon-based insulating layer formed using the susceptor 1330 having a flatness of 150 μm, and a display device of a graph 52 includes a silicon-based insulating layer formed using the susceptor 1330 having a flatness of 400 μm. A display device of a graph 53 includes a silicon-based insulating layer formed using the susceptor 1330 having a flatness of 550 μm.

The susceptors 1330 used for forming the silicon-based insulating layer included in the display device of the graph 51, the display device of the graph 52, and the display device of the graph 53 have the same or similar surface roughness. In addition, the susceptors 1330 used for forming the silicon-based insulating layer included in the display device of the graph 51, the display device of the graph 52, and the display device of the graph 53 have a first metal oxide layer (1330b, see FIG. 6) of the same or similar thickness.

Referring to FIG. 5, with a silicon-based insulating layer that was formed using the susceptor 1330 having a flatness of 150 μm, a defect occurred in a display device for the first time after the apparatus 1300 for manufacturing a display device was used approximately 13,000 times. In addition, with a silicon-based insulating layer that was formed using the susceptor 1330 having a flatness of 150 μm, defects occurred in approximately 3,359 display devices out of 20,000 display devices.

With a silicon-based insulating layer that was formed using the susceptor 1330 having a flatness of 400 μm, no defects occurred in a display device even after the apparatus 1300 for manufacturing a display device was used approximately 20,000 times. That is, if the flatness of the susceptor 1330 satisfies the above-described range, defects may not occur or may be reduced in a display device including a silicon-based insulating layer formed by using the apparatus 1300 even after the apparatus 1300 has been used for a long period of time.

With a silicon-based insulating layer that was formed using the susceptor 1330 having a flatness of 150 μm, a defect occurred in a display device for the first time after the apparatus 1300 for manufacturing a display device was used approximately 16,000 times. With a silicon-based insulating layer that was formed using the susceptor 1330 having a flatness of 550 μm, defects occurred in approximately 327 display devices out of 20,000 display devices. This may be because the flatness of the susceptor 1330 was too large and the thickness of the silicon-based insulating layer formed using the susceptor 1330 was not uniform. Accordingly, defects occurred in display devices including these silicon-based insulating layers.

FIG. 6 is a microscopic photographic image of the susceptor 1330 included in the apparatus 1300 for manufacturing a display device, according to an embodiment. FIG. 6 is a transmission electron microscopic photographic image of a cross-section of the susceptor 1330 included in the apparatus 1300 for manufacturing a display device, according to an embodiment.

Referring to FIG. 6, the susceptor 1330 may include a plurality of sublayers. The susceptor 1330 may include a first metal layer 1330a and a first metal oxide layer 1330b.

The first metal layer 1330a includes a sub-layer that occupies most of the susceptor 1330. The first metal layer 1330a occupying most of the susceptor 1330 may indicate that a thickness of the first metal layer 1330a is about 50% or more of a total thickness of the susceptor 1330. Specifically, the thickness of the first metal layer 1330a may be about 60% or more or about 70% or more of the total thickness of the susceptor 1330.

The susceptor 1330 may include at least one of aluminum (Al), magnesium (Mg), zinc (Zn), manganese (Mn), and copper (Cu). For example, the first metal layer 1330a may include aluminum (Al). Alternatively, the first metal layer 1330a may include an aluminum (Al)-zinc (Zn)-magnesium (Mg) alloy.

The first metal oxide layer 1330b may be disposed on the first metal layer 1330a. The first metal oxide layer 1330b may include the same metal element as that of the first metal layer 1330a. For example, the first metal oxide layer 1330b may include at least one of aluminum (Al), magnesium (Mg), zinc (Zn), manganese (Mn), and copper (Cu). However, the oxygen content of the first metal oxide layer 1330b may be higher than the oxygen content of the first metal layer 1330a. The first metal oxide layer 1330b may include an oxide of at least one of aluminum (Al), magnesium (Mg), zinc (Zn), manganese (Mn), and copper (Cu). That is, the first metal oxide layer 1330b may include an oxide of a metal included in the first metal layer 1330a. For example, if the first metal layer 1330a includes aluminum (Al), the first metal oxide layer 1330b may include aluminum oxide (Al₂O₃).

As described above, the susceptor 1330 is manufactured by performing an anodizing process on a preliminary susceptor on which a bead blasting process has been performed, and the first metal oxide layer 1330b is formed by the anodizing process. Therefore, the first metal layer 1330a and the first metal oxide layer 1330b may be provided integrally. As the first metal layer 1330a and the first metal oxide layer 1330b include the same metal element, an interface between the first metal layer 1330a and the first metal oxide layer 1330b may be identified using the oxygen content. For example, when analyzing the components along a direction (+z direction) from the first metal layer 1330a toward the first metal oxide layer 1330b, a section in which the oxygen content has increased may correspond to the first metal oxide layer 1330b.

A thickness of the first metal oxide layer 1330b may be about 7 μm to about 10 μm. Alternatively, the thickness of the first metal oxide layer 1330b may be about 8 μm to about 9 μm. Alternatively, the thickness of the first metal oxide layer 1330b may be about 8.2 μm to about 8.7 μm. If the thickness of the first metal oxide layer 1330b is less than the above range, a defect may occur in a display device including a silicon-based insulating layer formed by the apparatus 1300 for manufacturing a display device, which has been used for a long period of time. If the thickness of the first metal oxide layer 1330b exceeds the above range, generation of particles due to wear of the first metal oxide layer 1330b may increase.

With a silicon-based insulating layer that was formed using the susceptor 1330 having the first metal oxide layer 1330b with a thickness of 6.5 μm, current flowed toward a surface of the susceptor 1330 after the apparatus 1300 for manufacturing a display device was used approximately 10,000 times. With a silicon-based insulating layer that was formed using the susceptor 1330 having the first metal oxide layer 1330b having a thickness of 8.5 μm, no current flowed toward the surface of the susceptor 1330, even after the apparatus 1300 for manufacturing a display device was used approximately 20,000 times. That is, with the thickness of the first metal oxide layer 1330b of the susceptor 1330 being in the above-described range, a defect may not occur or may be minimized in a display device including a silicon-based insulating layer formed by the apparatus 1300 even after the apparatus 1300 has been used for a long period of time.

With a silicon-based insulating layer that was formed using the susceptor 1330 having the first metal oxide layer 1330b having a thickness of 11 μm, no current flow toward the surface of the susceptor 1330 was detected even after the apparatus 1300 was used approximately 20,000 times. However, with a silicon-based insulating layer that was formed using the susceptor 1330 having the first metal oxide layer 1330b with a thickness of 11 μm, generation of particles due to wear of the first metal oxide layer 1330b increases.

Below, a method of manufacturing a display device using the apparatus 1300 for manufacturing a display device described above is described. Various types of display device may be manufactured using the apparatus 1300. For example, the apparatus 1300 for manufacturing a display device may be used to manufacture a liquid crystal display device, a plasma display device, an organic light-emitting display device, etc. For convenience of description, the following description focuses on a display device manufactured as an organic light-emitting display device, using the apparatus 1300 for manufacturing a display device.

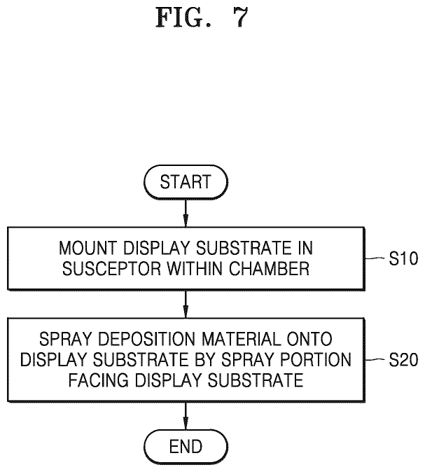

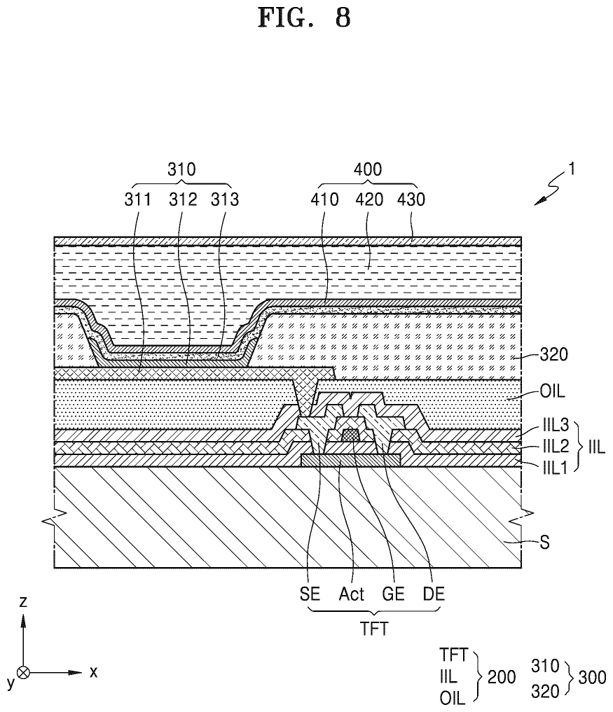

FIG. 7 is a flowchart of a method of manufacturing a display device, according to an embodiment. FIG. 7 is a flowchart of a method of manufacturing a display device using the apparatus 1300 for manufacturing a display device, described above with reference to FIGS. 1 to 6. That is, the method of FIG. 7, of manufacturing a display device may be implemented using the apparatus 1300 for manufacturing a display device, described above with reference to FIGS. 1 to 6. By using the method of manufacturing a display device, a portion of a display device 1 of FIG. 8 described below may be manufactured. For convenience, any descriptions that are substantially the same as those given above with reference to FIGS. 1 to 6 are omitted.

Referring to FIG. 7, the method of manufacturing a display device, according to an embodiment, may include operation S10 of mounting a display substrate on a susceptor and operation S20 of spraying a deposition material onto the display substrate.

In operation S10 of mounting a display substrate on a susceptor, the display substrate S may be mounted on the susceptor 1330 within the chamber 1310 of the apparatus 1300 for manufacturing a display device. That is, the display substrate S may be disposed on the susceptor 1330 within the chamber 1310 of the apparatus 1300 for manufacturing a display device. The display substrate S may include a substrate for a display device. One or more patterned or unpatterned layers may be formed or arranged on the display substrate S. The one or more patterned or unpatterned layers may be any layers suitable for a particular device. That is, when the display substrate S is placed on the susceptor 1330, the display substrate S may be in a state where one or more patterned or unpatterned layers are formed or arranged on the display substrate S.

In operation S20 of spraying a deposition material onto the display substrate, the deposition material may be sprayed onto the display substrate S by the spray portion 1340 facing the display substrate S. A deposition material may be sprayed onto the display substrate S within the chamber 1310 through a plurality of nozzles provided in the spray portion 1340. The deposition material may include a gas containing a component that is a raw material for a layer to be formed on the display substrate S. For example, the deposition material may include a gas containing components that are raw materials for a silicon-based insulating layer, such as silicon (Si), oxygen (O), or nitrogen (N). When the spray portion 1340 sprays the deposition material, plasma may be formed between the spray portion 1340 and the susceptor 1330. As the deposition material passes through a region where plasma is formed, radicals are formed, and the radicals may react on the display substrate S to form a silicon-based insulating layer.

The surface roughness of the susceptor 1330, the flatness of the susceptor 1330, and the thickness of the first metal oxide layer 1330b may satisfy the ranges described above with reference to FIGS. 1 to 6. In this case, even if a silicon-based insulating layer is formed by the apparatus 1300 for manufacturing a display device, which has been used for a long period of time, a defect in the display device including the silicon-based insulating layer may be prevented or reduced.

FIG. 8 is a cross-sectional view schematically illustrating the display device 1 manufactured according to an embodiment. As will be obvious to those skilled in the art, the display device 1 may include various other components in addition to the components shown.

The display device 1 may include the display substrate S and transistors and display elements formed by multiple layers formed on the display substrate S. The display device 1 may include the display substrate S, a pixel circuit layer 200, a display element layer 300, and an encapsulation layer 400.

The display substrate S may include glass, metal, or polymer resin. The display substrate S needs to be flexible or bendable. For example, the display substrate S may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. Various modifications may be made to the display substrate S. For example, the display substrate S may have a multilayer structure including two layers each including the above-described polymer resin and, between the two layers, a barrier layer including an inorganic material (e.g., silicon oxide (SiOₓ), silicon nitride (SiNₓ), or silicon oxynitride (SiOₓN_{y})).

The pixel circuit layer 200 may be disposed on the display substrate S. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3.

The semiconductor layer Act may be disposed on the display substrate S. The semiconductor layer Act may include polysilicon. Alternatively, the semiconductor layer Act may include amorphous silicon, an oxide semiconductor, an organic semiconductor, etc. In an embodiment, the semiconductor layer Act may include a channel region and a source region and a drain region respectively disposed on both sides of the channel region.

The gate insulating layer IIL1 may be disposed on the semiconductor layer Act and the display substrate S. The gate insulating layer IIL1 may include an inorganic insulating material such as silicon oxide (SiOₓ), silicon nitride (SiNₓ), or silicon oxynitride (SiOₓN_{y}).

The gate electrode GE may be disposed on the gate insulating layer IIL1. That is, by arranging the gate insulating layer IIL1 between the semiconductor layer Act and the gate electrode GE, insulation between the semiconductor layer Act and the gate electrode GE may be secured. The gate electrode GE may overlap with the channel region of the semiconductor layer Act. The gate electrode GE may include a low-resistance metal material. In an embodiment, the gate electrode GE may include a conductive material including molybdenum (Mo), aluminum (Al), copper (Cu), titanium (Ti), or the like, and may have a single-layer or multi-layer structure including the conductive material. In an embodiment, the gate electrode GE may have a multilayer structure of Ti/Cu/Ti.

The first interlayer insulating layer IIL2 may be disposed on the gate electrode GE and the gate insulating layer IIL1. The first interlayer insulating layer IIL2 may include an inorganic insulating material such as silicon oxide (SiOₓ), silicon nitride (SiNₓ), or silicon oxynitride (SiOₓN_{y}).

The source electrode SE and the drain electrode DE may be arranged on the first interlayer insulating layer IIL2. Each of the source electrode SE and the drain electrode DE may be connected to the semiconductor layer Act through a contact hole formed in the gate insulating layer IIL1 and the first interlayer insulating layer IIL2. At least one of the source electrode SE and the drain electrode DE may include a conductive material including molybdenum (Mo), aluminum (Al), copper (Cu), or titanium (Ti), and may have a single-layer or multi-layer structure including the conductive material. In an embodiment, at least one of the source electrode SE and the drain electrode DE may have a multilayer structure of Ti/Cu/Ti.

The second interlayer insulating layer IIL3 may be disposed on the source electrode SE, the drain electrode DE, and the first interlayer insulating layer IIL2. The second interlayer insulating layer IIL3 may include an inorganic insulating material such as silicon oxide (SiOₓ), silicon nitride (SiNₓ), or silicon oxynitride (SiOₓN_{y}).

The organic insulating layer OIL may be disposed on the second interlayer insulating layer IIL3. The organic insulating layer OIL may perform a function of generally flattening an upper portion of the pixel circuit layer 200. These organic insulating layers OIL may include organic materials such as acrylic, benzocyclobutene (BCB), or hexamethyldisiloxane (HMDSO). In FIG. 8, the organic insulating layer OIL is illustrated as a single layer, but various modifications are also possible, that is, the organic insulating layer OIL may be a multi-layer.

The display element layer 300 may be disposed on the pixel circuit layer 200. The display element layer 300 may include a display element 310 and a pixel-defining layer 320. The display element 310 may be electrically connected to the transistor TFT. The display element 310 may be, for example, an organic light-emitting diode having a pixel electrode 311, an opposite electrode 313, and an intermediate layer 312 arranged therebetween and including an emission layer. That the display element 310 is electrically connected to the transistor TFT may be understood as that the pixel electrode 311 of the organic light-emitting diode is electrically connected to the transistor TFT.

The pixel electrode 311 may be electrically connected to the transistor TFT by contacting either the source electrode SE or the drain electrode DE through a contact hole formed in the second interlayer insulating layer IIL3 and the organic insulating layer OIL. The pixel electrode 311 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 311 may further include a film including ITO, IZO, ZnO, or In₂O₃ above/below the above-described reflective layer.

The pixel-defining layer 320 may cover an edge of the pixel electrode 311. The pixel-defining layer 320 may have a pixel opening, and the pixel opening may overlap with the pixel electrode 311. The pixel opening may define an emission area of light emitted from the display element 310. The pixel-defining layer 320 may include an organic insulating material and/or an inorganic insulating material. In some embodiments, the pixel-defining layer 320 may include a light-blocking material.

The intermediate layer 312 may be disposed on the pixel electrode 311 and the pixel-defining layer 320. The intermediate layer 312 may include a low molecular weight material or a polymer material. If the intermediate layer 312 includes a low-molecular weight material, the intermediate layer 312 may have a structure in which a hole injection layer (HIL), a hole transport layer (HTL), an emission layer (EML), an electron transport layer (ETL), and an electron injection layer (EIL) are stacked in a single or composite structure, and may be formed by a vacuum deposition method. If the intermediate layer 312 includes a polymer material, the intermediate layer 312 may have a structure including a hole transport layer (HTL) and an emission layer (EML). The HTL may include PEDOT, and the EML may include a polymer material such as polyphenylene vinylene (PPV) and polyfluorene. The intermediate layer 312 may be formed by screen printing, inkjet printing, laser induced thermal imaging (LITI), etc. The intermediate layer 312 is not limited thereto and may have various structures. The intermediate layer 312 may include a layer that is integral across a plurality of pixel electrodes 311, or may include a layer patterned to correspond to each of the plurality of pixel electrodes 311.

The opposite electrode 313 may be disposed on the intermediate layer 312 and the pixel-defining layer 320. The opposite electrode 313 may be formed integrally with respect to a plurality of organic light-emitting diodes and correspond to the plurality of pixel electrodes 311. The opposite electrode 313 may include a light-transmitting conductive layer including ITO, In₂O₃ or IZO, and may also include a semi-transmitting film including a metal such as Al or Ag. For example, the opposite electrode 313 may be a semi-permeable membrane containing Mg or Ag.

As the display element 310 may be easily damaged by external moisture or oxygen, an encapsulation layer 400 may cover the display element 310 to protect the same. Referring to FIG. 8, the encapsulation layer 400 may include a first inorganic encapsulation layer 410, an organic encapsulation layer 420, and a second inorganic encapsulation layer 430.

The first inorganic encapsulation layer 410 may cover the opposite electrode 313. The first inorganic encapsulation layer 410 may include silicon oxide (SiOₓ), silicon nitride (SiNₓ), and/or silicon oxynitride (SiOₓN_{y}). That is, the first inorganic encapsulation layer 410 may be a silicon-based insulating layer. The first inorganic encapsulation layer 410 may be formed using the apparatus 1300 for manufacturing a display device. The first inorganic encapsulation layer 410 may be formed by spraying a deposition material onto the display substrate S.

For example, after the display substrate S is disposed on the susceptor 1330 in the chamber 1310 included in the apparatus 1300 for manufacturing a display device, the first inorganic encapsulation layer 410 may be formed by spraying a deposition material onto the display substrate S by the spray portion 1340 facing the display substrate S. When forming the first inorganic encapsulation layer 410, the display substrate S may be in a state in which the pixel circuit layer 200 and the display element layer 300 are formed on the display substrate S. That is, after the display substrate S with the opposite electrode 313 is mounted on the susceptor 1330 of the apparatus 1300, a vapor deposition process may be performed to form the first inorganic encapsulation layer 410.

The surface roughness of the susceptor 1330, the flatness of the susceptor 1330, and the thickness of the first metal oxide layer 1330b may satisfy the ranges described above with reference to FIGS. 1 to 6. In this case, even if the first inorganic encapsulation layer 410 is formed by the apparatus 1300 after a long period of usage, a defect in the display device 1 may be prevented or reduced.

Meanwhile, other layers, such as a capping layer, may be between the first inorganic encapsulation layer 410 and the opposite electrode 313. As the first inorganic encapsulation layer 410 is formed along a structure therebelow, an upper surface of the first inorganic encapsulation layer 410 may not be flat as shown in FIG. 8.

The organic encapsulation layer 420 covers the first inorganic encapsulation layer 410, and unlike the first inorganic encapsulation layer 410, an upper surface of the organic encapsulation layer 420 may be approximately flat. The organic encapsulation layer 420 may include one or more materials selected from the group consisting of polyethyleneterephthalate, polyethylenenaphthalate, polycarbonate, polyimide, polyethylenesulfonate, polyoxymethylene, polyarylate, and hexamethyldisiloxane. The second inorganic encapsulation layer 430 may cover the organic encapsulation layer 420 and may include silicon oxide (SiOₓ), silicon nitride (SiNₓ), and/or silicon oxynitride (SiOₓN_{y}).

As described above, the encapsulation layer 400 includes the first inorganic encapsulation layer 410, the organic encapsulation layer 420, and the second inorganic encapsulation layer 430. Through this multilayer structure, even if a crack occurs within the encapsulation layer 400, the crack may be prevented from being connected between the first inorganic encapsulation layer 410 and the organic encapsulation layer 420 or between the organic encapsulation layer 420 and the second inorganic encapsulation layer 430. Accordingly, formation of a path through which external moisture or oxygen may penetrate the display device 1 may be prevented or minimized.

The disclosure has been described with reference to the embodiments shown in the drawings, but these are only examples, and various modifications and other equivalent embodiments may be made thereto by those of ordinary skill in the art. Therefore, the scope of the disclosure should be determined by the appended claims.

According to an embodiment as described above, an apparatus for manufacturing a display device and a manufacturing method for a display device, which may reduce the possibility of defects occurring during a manufacturing process, may be implemented. However, the scope of the disclosure is not limited by the above-described effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display device, the apparatus comprising:
a chamber;
a susceptor positioned inside the chamber and configured to support a display substrate; and
a spray portion positioned to spray a deposition material toward the susceptor,
the susceptor having a surface roughness of about 19 μm to about 23 μm.

2. The apparatus of claim 1, wherein the susceptor has a flatness of about 200 μm to about 500 μm.

3. The apparatus of claim 1, wherein the susceptor comprises a first metal layer and a first metal oxide layer disposed on the first metal layer.

4. The apparatus of claim 3, wherein the first metal layer comprises at least one of aluminum, magnesium, zinc, manganese, and copper.

5. The apparatus of claim 3, wherein the first metal oxide layer comprises a same metal element as that of the first metal layer.

6. The apparatus of claim 5, wherein an oxygen content of the first metal oxide layer is higher than an oxygen content of the first metal layer.

7. The apparatus of claim 5, wherein the first metal oxide layer comprises an oxide of at least one of aluminum, magnesium, zinc, manganese, and copper.

8. The apparatus of claim 7, wherein the first metal layer comprises aluminum, and
the first metal oxide layer comprises aluminum oxide.

9. The apparatus of claim 3, wherein a thickness of the first metal oxide layer is about 7 μm to about 10 μm.

10. The apparatus of claim 3, wherein the first metal layer and the first metal oxide layer form a single body.

11. A method of manufacturing a display device, the method comprising:
mounting a display substrate on a susceptor inside a chamber, wherein a surface roughness of the susceptor is about 19 μm to about 23 μm; and
spraying a deposition material onto the display substrate using a spray portion directed toward the display substrate.

12. The method of claim 11, wherein a flatness of the susceptor is about 200 μm to about 500 μm.

13. The method of claim 11, wherein the susceptor comprises a first metal layer and a first metal oxide layer disposed on the first metal layer.

14. The method of claim 13, wherein the first metal layer comprises at least one of aluminum, magnesium, zinc, manganese, and copper.

15. The method of claim 13, wherein the first metal oxide layer comprises a same metal element as that of the first metal layer.

16. The method of claim 15, wherein an oxygen content of the first metal oxide layer is higher than an oxygen content of the first metal layer.

17. The method of claim 15, wherein the first metal oxide layer comprises an oxide of at least one of aluminum, magnesium, zinc, manganese, and copper.

18. The method of claim 17, wherein the first metal layer comprises aluminum, and
the first metal oxide layer comprises aluminum oxide.

19. The method of claim 13, wherein a thickness of the first metal oxide layer is about 7 μm to about 10 μm.

20. The method of claim 13, wherein the first metal layer and the first metal oxide layer form a single body.
